(19) United States
(12) Patent Application Publication
(10) Pub. No.: US 2004/0230934 A1
(43) Pub. Date: Nov. 18, 2004

(54) System and method for emulating systems with multiple field programmable gate arrays

(76) Inventors: Richard David Taylor, Eagle, ID (US); William Randolph Schmidt, Boise, ID (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/439,427

(22) Filed: May 15, 2003

(51) Int. Cl. G06F 17/50; H03K 19/00; G06F 9/455

(52) U.S. Cl. 716/17; 703/23

(57) ABSTRACT

A system and method for emulating an ASIC using multiple filed programmable gate arrays. A designer, using this method, emulates an integrated circuit design using a prototyping apparatus. The method includes reserving more than one location in a prototyping apparatus for a circuit block that is part of an ASIC design. Each of the reserved locations is coupled to a single interconnection point within the prototyping apparatus. By reserving more than one space for the possible locations of each circuit block, a designer can choose late in the design process where to finally place each circuit block, thereby allowing for design changes without problematic resynthesis and communication path reroutes.

### BACKGROUND OF THE INVENTION

Many of today's electronic systems use Application Specific Integrated Circuits (ASICs) to implement the various electronic control functions required for particular applications. ASICs are typically designed using a software platform to combine existing logic blocks, which are often stored in intellectual property libraries, along with newly designed logic blocks to create a new ASIC design. Due to the increasing size, complexity, and mask cost of contemporary ASICs, it is increasingly risky to design an ASIC using unproven-logic block designs, unproven logic-block combinations, and unproven logic-block interconnect methods.

As a result, a proposed ASIC design is often verified first by using a Field-Programmable Gate Array (FPGA) to emulate the proposed design. An FPGA is a type of logic chip that can be programmed and reprogrammed with a variety of programmable logic blocks using a typical design program with intellectual property libraries as mentioned above. An FPGA typically includes millions of transistor gates that can be programmed and coupled to realize logic functions, i.e., programmable logic blocks, for use in an electronic circuit. The FPGA also includes many pins that can be programmed to be inputs, outputs, and control terminals for interfacing with the various programmable logic blocks within the FPGA. Because FPGAs can be reprogrammed, they are effective for prototyping ASIC designs.

Prototyping is a methodology for implementing an ASIC design in single FPGA or multiple FPGA hardware to simulate and validate the functionality of the ASIC design at near real-time speeds. An ASIC design can be programmed into the FPGA hardware and simulated by using design software running on a typical computer platform. The computer platform typically includes an interface device for interfacing to a prototyping board which contains one or more FPGAs.

The prototyping board provides interconnections between the pins of one or more FPGAs and the interface device such that the software program can be used to manipulate each FPGA. Further, the prototyping board allows a designer to emulate I/O points of an ASIC through the connection between the interface device and the prototyping board by establishing routing paths. Routing paths are the physical interconnections between certain pins of an FPGA and the emulated I/O points of the prototyping board. For example, if a typical programmable logic block is programmed to be within a first FPGA and to use pins 10-20 for signal communication, routing paths between pins 10-20 of the first FPGA and respective I/O points of the prototyping board are established.

Once the ASIC design has been tested in an FPGA-prototyping environment, the Integrated Circuit (IC) or set of ICs containing the ASIC design can be mass-produced for faster performance and/or lower cost when used in actual application.

Because larger ASIC designs will typically require more than one FPGA, the designer will typically make design decisions as to which particular programmable logic blocks of an ASIC design will be assigned to which FPGA for simulation. One problem with larger ASIC designs is that it is often difficult for the designer to know which programmable logic blocks should go into which FPGA so as to realize the most efficient use of space and processing time. That is, the designer would like to know which programmable logic blocks will best fit within each of the FPGAs to use the resources within the FPGAs to maximum efficiency. Because a designer does not typically know the size of certain design parameters, such as, for example, the eventual size of an input/output block in an ASIC design, the designer encounters great difficulty in making these design decisions at the outset of the design process. As a result, the board routing paths initially chosen may turn out to be incorrect, and then must be changed as the locations of programmable logic blocks change. Unfortunately, this may cause delay in the design process because the routing paths change, and each FPGA must typically be resynthesized for the new routing paths.

One solution to not knowing certain design parameters at the beginning of the design process has been to use automatic partitioning tools, which are typically part of the design software that comes with a typical FPGA package. When using automatic partitioning tools, the designer uses the design software to input the ASIC design. The software may, periodically or on command, assess the ASIC design and make design decisions as to within which particular FPGA the respective programmable logic blocks will be located. If, after the first prototype, the design software decides to move certain programmable logic blocks from one FPGA to another, the routing paths for communication with the moved programmable logic blocks will typically also be changed.

There are a number of problems with this solution. First, such automatic partitioning tools are typically complex, and the signal timing of the resulting circuit is often arbitrary and unpredictable. As such, the timing performance of the resulting simulated ASIC design is likely to be poor and not a true reflection of the timing as it would be in the actual ASIC. Furthermore, if the designer or the software wishes to change the design to the point that routing changes must occur as well, the designer must also typically change the board level interconnect (the connections between the multiple FPGAs and the I/O points used to realize the routing paths) and each FPGA will typically have to be rerouted every time a change is made to the design. Because the automatic partitioning tool configures the communication routing for all the FPGAs simultaneously, the runtime of the rerouting function and subsequent resynthesis function of the automatic partitioning tool is typically long i.e., an entire day or longer with some large ASIC designs.

Another solution is the use of crossbar switches between various pins of each of the FPGAs. Crossbar switches help facilitate routing changes between multiple FPGAs and the I/O points of the prototyping board. Crossbar switches, which can be likened to a multiplexor, allow one or more pins of a first FPGA to be coupled to a first set of I/O points on the prototyping board when the crossbar switches are in a first position and also allow for one or more pins of a second FPGA to be coupled to the same set of I/O points on the prototyping board when the crossbar switches are in a second position. A typical crossbar connector may have multiple positions which are not necessarily mutually exclusive positions. Therefore, if a designer changes the design, the designer need not implement a hard wire change of a board level interconnect but can merely use the crossbar switch to implement the interconnection changes.

However, many of the problems described with respect to the automatic partitioning tools above still exist. For example, a complex software routing tool must still be used and the circuit timing may be poor due to the chosen partitioning. Further, the crossbar switches add additional delays that may degrade the timing performance of the emulated system. Moreover, resynthesis of each FPGA also requires more processing time. In addition, more board level components are needed, i.e., the crossbar switches, and the crossbar switches must be reprogrammed as well every time the pin outs of the FPGAs change during rerouting.

A third solution is the use of a manual ad-hoc partitioning technique where the designer makes a best guess at how the circuit should be partitioned between the FPGAs. Problems with this solution, much as described above, are still prevalent. For example, a relatively high design effort on the part of the designer is still required, and the designer must know the design content and size before partitioning. Any changes are likely to require at least one or more board level interconnect changes and, thus, the FPGAs that are affected by the chosen change must be resynthesized. Even though, the resynthesizing may be limited to one or fewer than all of the FPGAs, the added runtime of the design software is still a drawback. Furthermore, it is still difficult to achieve predictable timing with this solution and it is typically difficult to leverage or expand the design without starting over from the beginning of the design process.

### SUMMARY OF THE INVENTION

An embodiment of the present invention includes a system and method for emulating an ASIC using multiple FPGAs. A designer, using this method, emulates an integrated circuit design using a prototyping apparatus that includes more than one FPGA that may be programmed with circuit blocks. The method includes reserving more than one location in a prototyping apparatus for a circuit block that is part of an ASIC design. Each of the reserved locations is coupled to a single interconnection point within the prototyping apparatus. By reserving more than one space for the possible locations of each circuit block, a designer can choose late in the design process where to finally place each circuit block, thereby allowing for design changes without problematic resynthesis and communication path reroutes.

Modern FPGAs allow such an embodiment of the invention to be implemented because many of today's FPGAs have a large number (typically 400 or more) of I/O pins (such FPGAs are available from Xylynx and Altera). As such, more pins are available to be assigned to various programmable logic blocks in the ASIC design. For example, a designer may use approximately 250 pins for implementing a bus bridge extension (i.e., the connection of the internal buses between multiple FPGAs) and approximately 50 pins for a reserve sideband communications bus. This leaves a large number of pins on each FPGA such that multiple pins may be reserved on each FPGA for a possible location of unknown programmable logic blocks. Later, when unchosen locations are freed up, the pins may be used for other purposes. As a result, design changes can be implemented more readily during the design process.

### BRIEF DESCRIPTION OF THE DRAWINGS

The foregoing aspects and many of the attendant advantages of the invention will become more readily appreciated as the same become better understood by reference to the following detailed description, when taken in conjunction with the accompanying drawings, wherein:

FIG. 1 is a block diagram of a prototyping board having multiple FPGAs according to an embodiment of the invention;

FIG. 2 is a block diagram of an example ASIC design that may be implemented with the prototyping board of FIG. 1 according to an embodiment of the invention;

FIG. 3 is a block diagram of an example of the ASIC design of FIG. 2 implemented in the prototyping board of FIG. 1 according to an embodiment of the invention; and

FIG. 4 is a block diagram of a system that includes the prototyping board of FIG. 1 according to an embodiment of the invention.

### DETAILED DESCRIPTION

The following discussion is presented to enable a person skilled in the art to make and use the invention. The general principles described herein may be applied to embodiments and applications other than those detailed below without departing from the spirit and scope of the present invention. The present invention is not intended to be limited to the embodiments shown, but is to be accorded the widest scope consistent with the principles and features disclosed or suggested herein.

A method for designing an ASIC using multiple FPGAs that includes reserving space in each FPGA for one or more programmable logic blocks having unknown sizes at the beginning of the design process allows for relatively easy design changes at a point later in the design process without the problems as described above. Briefly, using a software design program running on a computer platform which is coupled to a prototyping board containing one or more FPGAs through an interface device, a designer first chooses programmable logic blocks with known sizes and assigns these blocks to respective spaces within one or more of the FPGAs. Next, programmable logic blocks with unknown sizes or programmable logic blocks that a designer knows may change location during the design process are assigned to respective reserved spaces in each FPGA. Upon assigning the reserved space, the pins of multiple ones of the FPGAs that correspond to the reserved space are coupled together with board level interconnects and subsequently coupled to the corresponding I/O points of the prototyping board. As such, later during the design phase, when the designer decides that a particular unknown block is now known enough to definitively assign it to a dedicated place within one FPGA, the board level interconnects are already in place and the designer may simply ignore the reserved space in the unchosen FPGA reserved spaces.

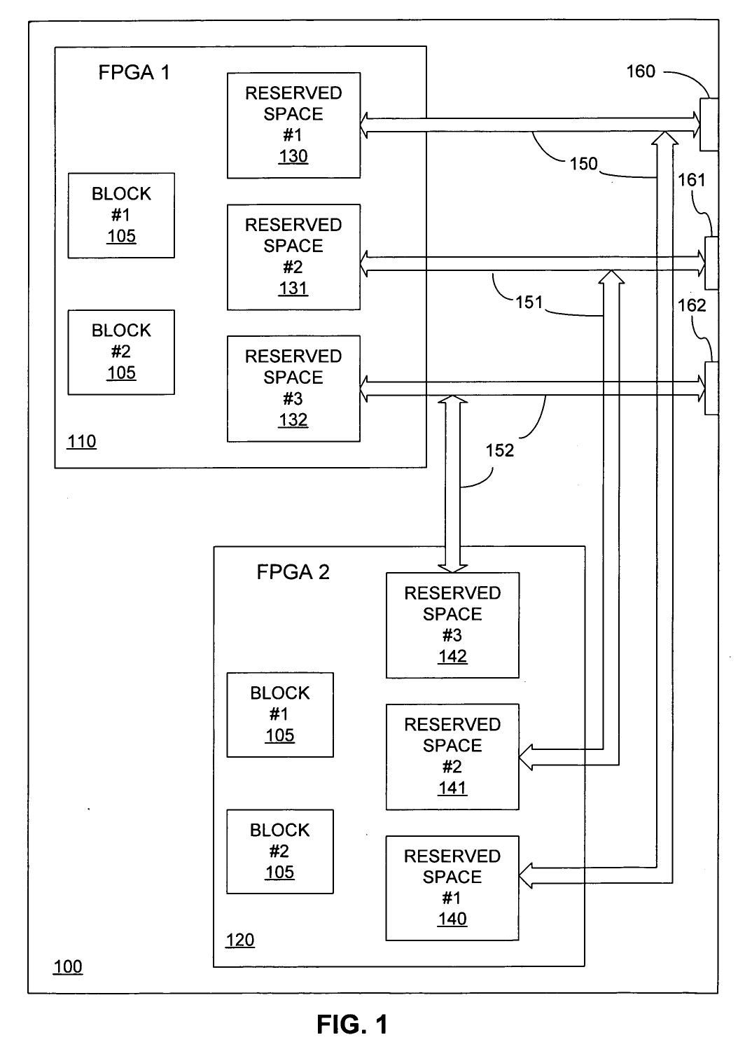

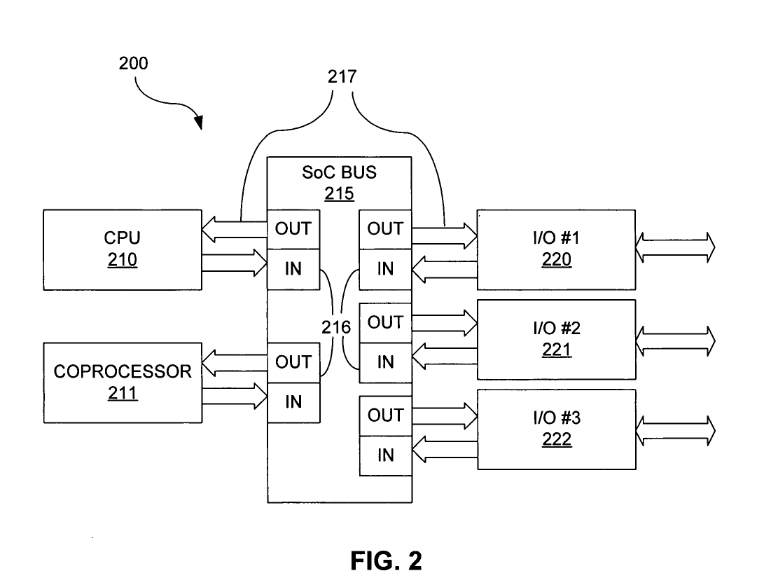

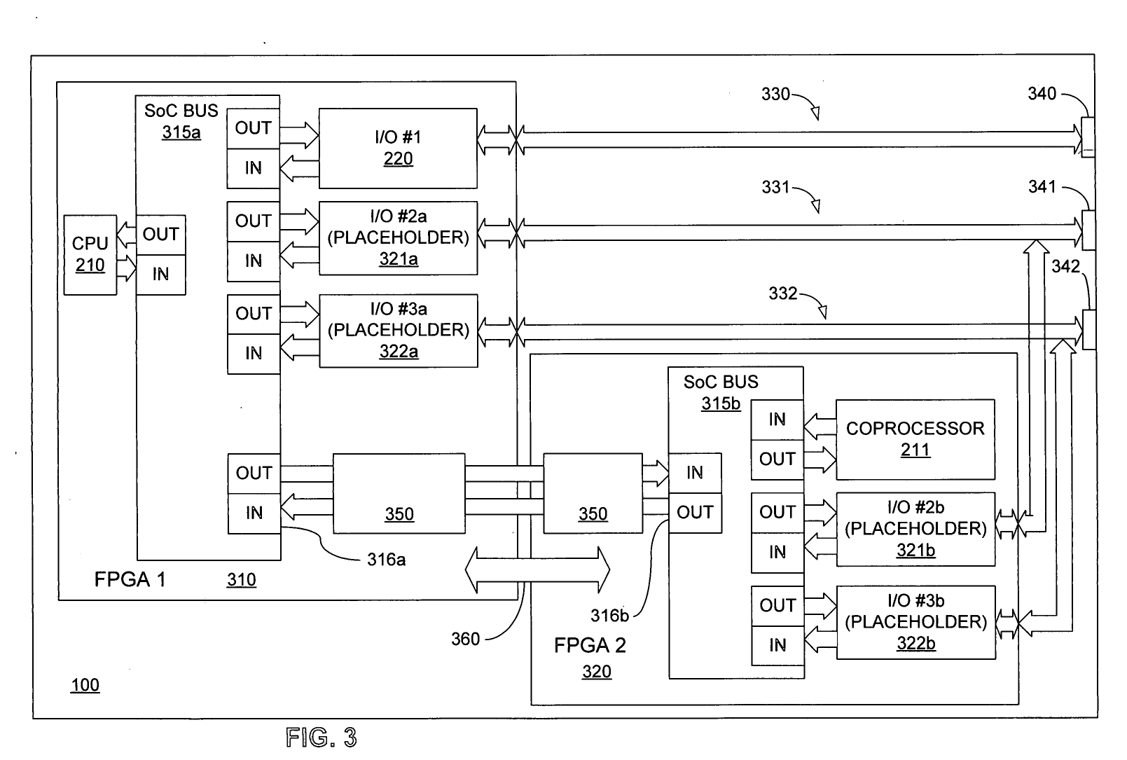

FIG. 1 is a block diagram of a suitable prototyping board and environment for practicing a system and method of an embodiment of the present invention while FIGS. 2 and 3 present an example of a design process using a method of an embodiment of the present invention.

With reference to FIG. 1, a block diagram of a prototyping board 100 is shown with a plurality of FPGAs arranged therein. The arrangement of the FPGAs is not relevant nor is the size of the FPGAs themselves. A typical size, however, for an FPGA suitable for use with the present invention is an FPGA containing six million logic gates or more. Furthermore, the prototyping board 100 may contain any number of FPGAs including a single FPGA and each FPGA may be of a different size.

The prototyping board 100 includes a first FPGA 110 and a second FPGA 120. Each FPGA 110 and 120 may include one or more blocks 105 that are representations of various logical circuits and/or programmable logic blocks as programmed by a designer during the design process. The blocks 105 may be designed using design software (not shown) in conjunction with a typical computer platform (not shown) coupled with the prototyping board 100 and are simply a representation of a programmed set of gates. A block 105 may be a logical partitioning of gates within the FPGA 110 for use for a particular purpose, such as, for example, an I/O block or a memory block.

During the design process, the designer chooses the location and the purpose of the blocks 105 using the design software. When a location in an FPGA 110 or 120 is chosen, pins (not shown) of the chosen FPGA 110 that correspond to the chosen location may be coupled with I/O points 160, 161, and 162 in the prototyping board 100.

If the designer, however, is not sure of the best location for a particular block, as is often the case, the designer may reserve space within several FPGAs or different spaces within one FPGA and then choose later. Here, three such unknown blocks exist that need to be reserved in both FPGAs 110 and 120. The first FPGA 110 includes reserved space #1 130, reserved space #2 131 and reserved space #3 132. Likewise, the second FPGA 120 also includes three such blocks, reserved space #1 140, reserved space #2 141 and reserved space #3 142.

These reserved spaces are respectively coupled to each other and to respective I/O points 160, 161, and 162 on the prototyping board 100 with board level interconnects 150, 151, and 152. For example, the reserved space #1 130 of the first FPGA 110 is coupled with the reserved space #1 140 of the second FPGA 120 and the I/O point 160 via a first board level interconnection 150. Similarly, the reserved space #2 131 of the first FPGA 110 is coupled with the reserved space #2 141 of the second FPGA 120 and to the I/O point 161 via a second board level interconnection 151. Finally, the reserved space #3 132 of the first FPGA 110 is coupled with the reserved space #3 142 of the second FPGA 120 and the I/O point 162 via a third board level interconnection 152.

As such, while the board level interconnections 150, 151, and 152 are coupled in this manner, any design accessing a logic block within a particular reserved space of the first FPGA 110 will also be accessing the corresponding logic block in the corresponding reserved space of the second FPGA 120. Furthermore, additional reserved spaces in additional FPGAs (not shown) may also be coupled with the board level interconnections 150, 151, and 152, thus creating additional redundancies in accessing particular logic blocks in an ASIC design. This allows a designer to have flexibility as to where to put any given programmable logic block as the design develops, but without necessitating board level interconnection changes and without using automatic partitioning tools. The following non-limiting example will help to illustrate the design process according to this embodiment of the present invention.

With reference to FIG. 2, a block diagram of an example of a design that would benefit from the method and system of an embodiment of the present invention is shown. A designer wishes to implement a circuit 200 that will likely require at least two FPGAs and the location of the specific programmable logic blocks is not established because the designer may not yet know how big each programmable logic block will be when the final design is complete. The circuit 200 includes a central processing unit 210 (CPU), a coprocessor 211, a system-on-chip (SoC) bus 215 (the backplane), and three I/O blocks 220, 221, and 222. The processor 210 and coprocessor 211, and I/O blocks 220, 221, and 222 are well known programmable logic block applications as is the backplane 215 which is operable to facilitate communication between the various other programmable logic blocks. Examples of a backplane 215 include backplanes for VCI or AMBA. The communication channels 217 between programmable logic blocks and the backplane 215 are represented by input/output spigots 216 within the backplane. 215. Since these programmable logic block applications are well known, they will not be discussed in detail.

The number of gates required for a typical CPU 210 and coprocessor 210 is generally known as is the number of gates for the backplane 215, but the I/O blocks 220, 221, and 222 may be of any size and will depend upon the application for which the ASIC is being designed. As such, a designer would do well to reserve space in a number of FPGAs for the possible locations of the I/O blocks 220, 221, and 222, as is the case with respect to FIG. 3.

With reference to FIG. 3, the circuit 200 of FIG. 2 may be designed using a prototyping board 100 shown in FIG. 1. Two FPGAs 310 and 320 are placed onto a prototyping board 100 that has board level interconnections 330 between certain pins (not shown individually) of the first FPGA 310 and certain pins of the second FPGA 320. The board level interconnections 330 are chosen based upon the design being implemented during the design process.

Here, the design chosen is the circuit 200 of FIG. 2. As such, the designer typically knows that the CPU 210 will fit on the first FPGA 310 and that the coprocessor will fit on the second FPGA 320. Furthermore, the designer may make a design choice that I/O block #1 220 will also fit on the first FPGA 310 as well. Of course, since the design spans two different FPGAs, the backplane 315 is implemented in both FPGAs 310 and 320: a first logical portion 315a in the first FPGA 310 and a second logical portion 315b in the second FPGA 320. The two logical portions 315a and 315b of the backplane 315 can be connected to one another as if the second logical portion 315b of the backplane 315 is merely another programmable logic block connected to the first portion 315a of the backplane 315. Specifically, input/output spigots 316a and 316b are assigned for the coupling between the logical portions 315a and 315b of the backplane 315, which allows the backplane to be segmented between the two FPGAs 310 and 320. Of course, on the actual ASIC, there will typically only be a single backplane 315.

The designer, however, may not know what the actual size of or best location for I/O block #2 221 and I/O block #3 222 will eventually be. Therefore, the designer chooses placeholders in each FPGA 310 and 320 for these programmable logic blocks and couples the respective pins corresponding to the reserved placeholders of each FPGA 310 and 320 together. As shown in FIG. 3, I/O placeholder #2a 321a and I/O placeholder #2b 321b are coupled together via a board level interconnect 331. Likewise, I/O placeholder #3a 322a and I/O placeholder #3b 322b are also coupled together via a board level interconnect 332. As such, when a designer chooses to access an FPGA 310 or 320 through the respective I/O points 341 and 342 of the prototype board 100, both FPGAs 310 and 320 will be accessed.

By using this method and system, the designer is able, at the beginning of the design phase, to reserve placeholders for certain programmable logic blocks on more than one FPGA. Since these placeholders are hardwired together on the prototype board 100 via the board level interconnections 330, wherever the designer chooses to eventually place the actual I/O block #2 321 will not affect the board level interconnections 330. Therefore, the designer can easily choose in which FPGA 310 or 320 to implement the 10 block #2 321 without having to change the board level interconnections 330. The same is true for I/O block #3 322.

In another embodiment of the invention, an optional pipeline interface 350 is implemented between the first and second logical portions 315a and 315b of the backplane 315. The pipeline interface 350 allows the backplane 315 timing to be isolated from the inter-FPGA interface timing. This may add pipeline latency to the communications between the two FPGAs 310 and 320, but will typically allow the first 315a and second 315b portions of the backplane 315 in each FPGA 310 and 320 to run at a higher clock frequency. This also has the advantage of effectively isolating the timing between the two FPGAs 310 and 320 so that the timing constraints of the individual FPGAs 310 and 320 are predictable and more easily met.

The pipeline interface 350 may be synchronous, or it may be asynchronous to permit the two FPGA backplanes 315a and 315b to operate at differing clock frequencies. For applications where the additional pipeline data latency is not acceptable, or when it is desirable to more accurately model the final ASIC backplane 315 latencies, the pipeline interface 350 can be omitted. However, this configuration may require the FPGAs 310 and 320 to be clocked at a lower frequency due to the longer and less predictable delay paths.

Pipelining communications, whereby data is sent between programmable logic blocks in rapid succession without waiting for notification of receipt, is well known in the industry and will not be discussed further herein. Although there is typically data latency between the two FPGAs 310 and 320 by pipelining the communications, the actual timing can be better preserved if the data latency is ignored. However, the designer may choose not to use the pipelining function in lieu of a more real-time simulation.

In another embodiment of the invention, the prototype board 100 includes a sideband interface bus 360 that couples predetermined pins of the first FPGA 310 to predetermined pins of the second FPGA 320 for standard “sideband” communication signals that are not typically associated with I/O points 340, 341 and 342 of an eventual ASIC. Sideband communication signals include interrupt requests, DMA handshakes, clocks, time base pulses, etc. Thus, instead of using a board level interconnection 330 that may change with the design to interconnect the two FPGAs 310 and 320 for these “sideband” communications, individual pins of each FPGA 310 and 320 are allowed to be assigned a certain sideband communication signals between the FPGAs 310 and 320.

For example, if there is an interrupt signal from the co-processor 211 on the second FPGA 320 to the CPU 210 on the first FPGA 310, this interrupt signal may be passed through the sideband interface bus 360. By hardwiring such a sideband bus 360 into the prototype board 100, a designer can utilize the sideband bus 360 without having to make board level changes when changes are made internally to one of the FPGAs 310 and 320.

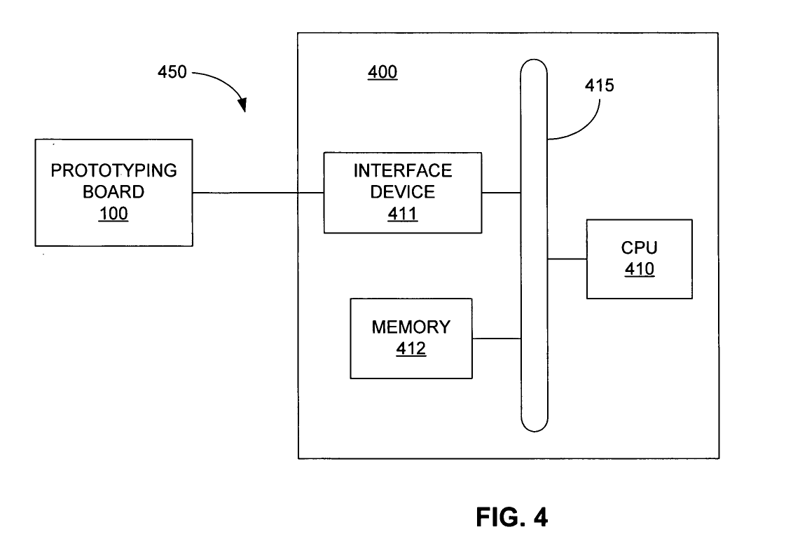

FIG. 4 is a block diagram of a suitable system 450 for practicing the method and system described above according to an embodiment of the invention. The prototyping board is coupled with a computer system 400 via an interface device 411. The interface device 411 provides an interface to a bus 415 within the computer system which provides for communications with a CPU 410. Design software (not shown) resides within a memory 412 that is also communicatively coupled with the CPU 410 though the bus 415. A designer may use the computer platform 400 and the design software to implement an ASIC design in the prototyping board 100 for simulation and testing.

We claim:

1. A method for emulating an integrated circuit design having at least one circuit block, the method comprising:
reserving more than one location in a prototyping apparatus for the circuit block; and
coupling each of the more than one reserved locations to a single interconnection point within the prototyping apparatus.

2. The method of claim 1, further comprising:
selecting one of the reserved locations; and
decoupling each reserved location other than the selected reserved location from the interconnection point.

3. The method of claim 2 wherein selecting further comprises determining a
reserved location that exhibits suitable communication efficiency.

4. The method of claim 1 wherein each of the more than one reserved locations is disposed on a single programmable logic circuit.

5. The method of claim 1 wherein each of the more than one reserved locations is disposed on a separate programmable logic circuit.

6. The method of claim 5, further comprising
locating a bus within each of the separate programmable logic circuits; and
coupling each of the busses together.

7. The method of claim 6, further comprising pipelining communication signals on the coupled busses.

8. The method of claim 5, further comprising coupling a bus between each of the programmable logic circuits, the bus operable to facilitate communication of signals between each of the programmable logic circuits.

9. A prototyping apparatus comprising:
a first programmable logic circuit and a second programmable logic circuit, each programmable logic circuit having a reserved space for a circuit block; and
a routing path that couples each of the reserved spaces together, the routing path operable to facilitate communications between each reserved space.

10. The prototyping apparatus of claim 9 wherein each programmable logic circuit comprises a field programmable gate array.

11. The prototyping apparatus of claim 9 wherein each reserved space in each programmable logic circuit comprises a plurality of gates operable to be accessed by pin connections to the routing path.

12. The prototyping apparatus of claim 9, further comprising a bus disposed within each programmable logic circuit.

13. The prototyping apparatus of claim 12, further comprising a pipeline interface between each bus disposed within each programmable logic circuit.

14. The prototyping apparatus claim 12, further comprising an external bus operable to facilitate bus communication signals between each of the programmable logic circuits.

15. The prototyping apparatus claim 9, further comprising a prototyping board coupled with each of the programmable logic circuits.

16. A prototype apparatus comprising:
a prototype board;
a first programmable logic circuit and a second programmable logic circuit, each programmable logic circuit having a reserved space for a circuit block;
a routing path that couples each of the reserved spaces together, the routing path operable to facilitate communications between each reserved space; and
at least one input/output point coupled with the routing path.

17. The prototype apparatus of claim 16, further comprising:
at least one second reserved space in each programmable logic circuit for a second circuit block;
a second routing path coupled with each of the at least one second reserved spaces, and
at least one second input/output point coupled with the second routing path.

18. An electronic system comprising:
a prototyping board comprising:
a first programmable logic circuit and a second programmable logic circuit, each programmable logic circuit having a reserved space for a circuit block;
a routing path that couples each of the reserved spaces together, the routing path operable to facilitate communications between each reserved space;
at least one input/output point coupled with the routing path; and
an interface device disposed within a computer system, the interface device operable to facilitate communication between a software platform and the prototyping board.

19. The electronic system of claim 18 wherein the software platform is operable to determine the most efficient configuration of the interconnection bridge.

20. The electronic system of claim 18, further comprising a processor coupled to the interface device
